(19) United States
(12) Patent Application Publication
(10) Pub. No.: US 2026/0239625 A1
(43) Pub. Date: Aug. 13, 2026

(54) SEMICONDUCTOR MANUFACTURING HIGH-K DIELECTRIC BY HZZ STACK

(71) Applicant: NANYA TECHNOLOGY CORPORATION, New Taipei City (TW)

(72) Inventors: Jyun-Hua YANG, New Taipei City (TW); Chun Lin LU, New Taipei City (TW)

(21) Appl. No.: 19/052,312

(22) Filed: Feb. 13, 2025

(51) Int. Cl. H10B 53/30

(52) U.S. Cl. CPC H10B 53/30

(57) ABSTRACT

A memory device includes a substrate and a capacitor structure over the substrate. The capacitor structure comprising: a lower electrode; a capacitor dielectric over the lower electrode and having a first dielectric and a second dielectric over the first dielectric, wherein the first dielectric is made of hafnium oxide and the second dielectric is made of zirconium oxide; and an upper electrode over the second dielectric.

### BACKGROUND

The present invention relates to a memory device and a method of making the same. During DRAM capacitor scaling, a lot of effort was put searching for new material stacks to overcome the scaling limitations of the current material. As the capacitance is limited by scale down of capacitor, and thus higher k-value dielectric is required to achieve reasonable capacitance. The utilization of the morphotropic phase boundary (MPB) between the newly found ferroelectric orthorhombic phase and the tetragonal phase in a HfO₂-ZrO₂ is suggested for high capacitance dielectric capacitor. Being different from other high-k dielectrics, where the k-value decreases with the decreasing film thickness, these films showed increasing k-values with decreasing film thickness.

### SUMMARY

One aspect of the present disclosure provides a memory device, comprising a substrate and a capacitor structure over the substrate. The capacitor structure comprising: a lower electrode; a capacitor dielectric over the lower electrode and having a first dielectric and a second dielectric over the first dielectric, wherein the first dielectric is made of hafnium oxide and the second dielectric is made of zirconium oxide; and an upper electrode over the second dielectric.

In some embodiments, the second dielectric is doped with aluminum.

In some embodiments, an aluminum concentration of the second dielectric is from about 1% to about 8%.

In some embodiments, the first dielectric is free of aluminum.

In some embodiments, the first dielectric has a first thickness, and the second dielectric has a second thickness different from the first thickness.

In some embodiments, the first thickness is less than the second thickness.

In some embodiments, the first thickness of the first dielectric is from about 0.5 nm to about 2.0 nm, and the second thickness of the second dielectric is from about 3.0 nm to about 7.0 nm.

In some embodiments, the capacitor dielectric has a crystalline structure with tetragonal phase and orthorhombic phase.

In some embodiments, a ratio of tetragonal phase to orthorhombic phase of the capacitor dielectric is about 0.1 to about 0.3.

In some embodiments, the memory device further comprising: a word line structure over the substrate; and a bit line structure over the substrate and electrically connected to a doped region of the substrate on a first side of the word line structure, wherein the capacitor structure is electrically connected to another doped region of the substrate on a second side of the word line structure.

One aspect of the present disclosure provides a method for forming a memory device, comprising: forming a capacitor structure over a substrate, comprising: depositing a bottom electrode; depositing a first dielectric over the bottom electrode, wherein the first dielectric is made of hafnium oxide; depositing a second dielectric over the first dielectric, wherein the second dielectric is made of zirconium oxide; and depositing a top electrode over the second dielectric.

In some embodiments, the second dielectric is doped with aluminum.

In some embodiments, an aluminum concentration of the second dielectric is from about 1% to about 8%.

In some embodiments, the first dielectric is free of aluminum.

In some embodiments, the first dielectric has a first thickness, and the second dielectric has a second thickness different from the first thickness.

In some embodiments, the first thickness is less than the second thickness.

In some embodiments, the method further comprising performing an anneal process after depositing the second dielectric, such that a combination of the first dielectric and the second dielectric has a crystalline structure with tetragonal phase and orthorhombic phase.

In some embodiments, a temperature of the anneal process is between about 400° C to about 500° C.

In some embodiments, a ratio of tetragonal phase to orthorhombic phase is about 0.1 to about 0.3.

In some embodiments, the method further comprising: forming a word line structure over the substrate; and forming a bit line structure over the substrate and electrically connected to a doped region of the substrate on a first side of the word line structure, wherein the capacitor structure is electrically connected to another doped region of the substrate on a second side of the word line structure.

It is to be understood that both the foregoing general description and the following detailed description are by examples, and are intended to provide further explanation of the invention as claimed.

### BRIEF DESCRIPTION OF THE DRAWINGS

The invention can be more fully understood by reading the following detailed description of the embodiment, with reference made to the accompanying drawings as follows:

FIG. 1 is a schematic diagram depicting a capacitor structure according to some embodiments of the present disclosure.

FIG. 2 is a circuit diagram of a memory cell of a memory device according to some embodiments of the present disclosure.

FIG. 3 is a cross-sectional view of a memory device according to some embodiments of the present disclosure.

FIGS. 4 to 12 are cross-sectional views at various stages of forming a memory device according to some embodiments of the present disclosure.

### DETAILED DESCRIPTION

Reference will now be made in detail to the present embodiments of the invention, examples of which are illustrated in the accompanying drawings. Wherever possible, the same reference numbers are used in the drawings and the description to refer to the same or like parts.

As used herein, “around”, “about”, “approximately”, or “substantially” may generally mean within 20 percent, or within 10 percent, or within 5 percent of a given value or range. Numerical quantities given herein are approximate meaning that the term “around”, “about”, “approximately”, or “substantially” can be inferred if not expressly stated. One skilled in the art will realize, however, that the values or ranges recited throughout the description are merely examples, and may be reduced or varied with the sown-scaling of the integrated circuits.

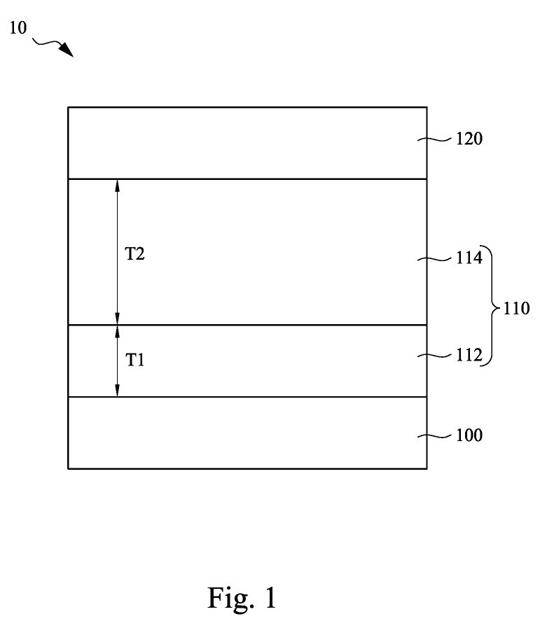

FIG. 1 is a schematic diagram depicting a capacitor structure according to some embodiments of the present disclosure. As shown in FIG. 1, a capacitor structure 10 includes a bottom electrode 100, a capacitor dielectric 110 over the bottom electrode 100, and a top electrode 120 over the capacitor dielectric 110. The capacitor dielectric 110 includes a first dielectric 112 and a second dielectric 114 over the first dielectric 112. In some embodiments, the bottom electrode 100 and the top electrode 120 may be formed of, for example, TiN, Ti, W, WN, Pt, Ir, Ru, and other conductive materials.

In some embodiments, the first dielectric 112 and the second dielectric 114 may be made of different high-k dielectric materials. For example, the first dielectric 112 may include hafnium oxide (HfO₂). On the other hand, the second dielectric 114 may include zirconium oxide (ZrO₂). In some embodiments, the second dielectric 114 (e.g., ZrO₂) may be doped with aluminum (Al) at a concentration between about 1% to about 8% to suppress leakage current. In some embodiments, the first dielectric 112 may be free of aluminum. That is, the aluminum concentration in the first dielectric 112 may be lower than the aluminum concentration in the second dielectric 114.

The first dielectric 112 has a thickness T1, and the second dielectric 114 has a thickness T2. In some embodiments, the thickness T1 is different from the thickness T2. In some embodiments, the thickness T2 is greater than the thickness T1. In some embodiments, the thickness T1 is in the range of about 0.5 nm to about 2.0 nm, and the thickness T2 is in the range of about 3.0 nm to about 7.0 nm. In some embodiments, the ratio of the thickness T1 to the thickness T2 may be in the range of about 1.5 to about 14.

Based on the above described architecture, the capacitor dielectric 110, which includes the first dielectric 112 and the second dielectric 114, may include a crystalline structure having tetragonal phase and orthorhombic phase. In some embodiments, the ratio of the tetragonal phase to the orthorhombic phase of the capacitor dielectric 110 may be in the range of about 0.1 to about 0.3 (e.g., 0.2) measured by a technique such as x-ray diffraction (XRD).

The fabrication method results in the capacitor structure 10, will be described in further detail below. As shown in FIG. 1, in some embodiments, the bottom electrode 100, the first dielectric 112, the second dielectric 114 and the top electrode 120 may be sequentially deposited by chemical vapor deposition (CVD), PECVD, low pressure CVD (LPCVD), ultra-high vacuum CVD (UHVCVD), or other suitable deposition processes, for example.

In some embodiments where the second dielectric 114 is made of zirconium oxide (ZrO₂), the second dielectric 114 can be formed using a CVD process. In a CVD process, a zirconium source (e.g., ZrCl₄), an oxygen source (e.g., oxygen), and a carrier gas (e.g., argon or nitrogen) are supplied into a CVD chamber. The chamber of the CVD process is controlled to achieve an adequate temperature, fostering the decomposition of the zirconium source and subsequent reaction with oxygen source present in the chamber, so as to form the zirconium oxide film. In some embodiments where the second dielectric 114 is made of zirconium oxide (ZrO₂) doped with aluminum (Al), an aluminum source (e.g., trimethylaluminum (TMA) or aluminum chloride) may also be supplied into the CVD chamber during the CVD process. In such embodiments, the flow rate of the aluminum source may be less than the flow rate of the zirconium source, resulting in an aluminum concentration in a range of about 1% to about 8%.

In other embodiments where the second dielectric 114 is made of zirconium oxide (ZrO₂) doped with aluminum (Al), the second dielectric 114 can be formed using an ALD process. The ALD process may include alternately performing several zirconium oxide (ZrO₂) deposition cycles and aluminum oxide (Al₂O₃) deposition cycles in an alternate manner, until the second dielectric 114 achieve a desired thickness.

Furthermore, before depositing the top electrode 120, performing an anneal process to the capacitor dielectric 110. The temperature of the anneal process is between about 400° C to about 500° C. After the anneal process, the capacitor dielectric 110 are crystallized to ideal crystal phase. In some embodiments, the ratio of the tetragonal phase to the orthorhombic phase of the capacitor dielectric 110 may be in the range of about 0.1 to about 0.3 (e.g. 0.2) measured by a technique such as x-ray diffraction (XRD). In other embodiment, the condition equivalent oxide thickness (EOT) of the capacitor dielectric 110 may be about 0.6 nm, so as to achieve an increasing capacitance and to reduce leakage current.

Although only planar-type capacitors are illustrated above in FIG. 1, the spirit of the present disclosure can also be applied to capacitors with different designs such as cylinder-type capacitors or pedestal-type capacitors.

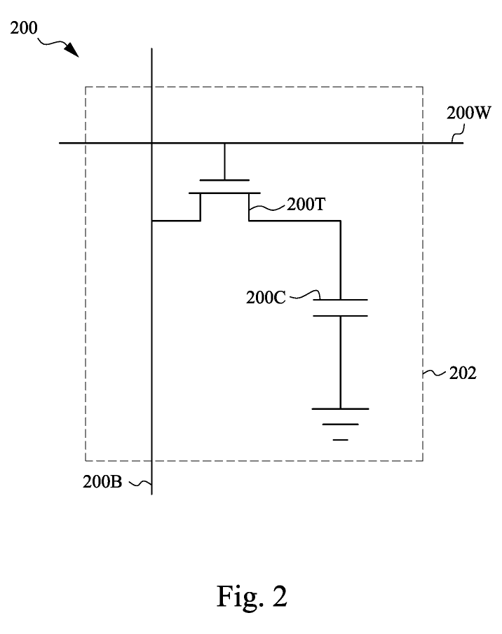

FIG. 2 is a circuit diagram of a memory cell of a memory device according to some embodiments of the present disclosure. With reference to FIG. 2, a memory device 200 consists of multiple memory cells 202 arranged in a rectangular matrix configuration. In some embodiments, the memory device 200 is a dynamic random access memory (DRAM) device. The memory cell 202 of the memory device 200 consists of a transistor 200T and a capacitor 200C electrically connected to the transistor 200T as main structures. The one side of capacitor 200C is coupled with the drain region of the transistor 200T and the other side of the capacitor 200C is coupled to the ground. The memory device 200 further includes a word line 200W coupled with the gate region of the transistor 200T, and a bit line 200B coupled with the source of the transistor 200T. Specifically, the memory cell 202 stores a logical value (either 0 or 1) using the capacitor 200C. If the capacitor 200C is in an empty state (i.e., no charge), it represents a logic value of 0. If the capacitor 200C is in a fully-charged state, it represents a logic value of 1. The transistor 200T controls the channel to the memory cell 202 by opening or closing the gate of the transistor 200T, allowing the value to be read or written. Writing data involves charging or discharging the capacitor 200C, while reading data detects the charges to determine the stored logical value.

With reference to FIG. 2, a word line 200W connected to the transistor 200T is used to control the gate of the transistor 200T by applying a voltage to the transistor 200T, allowing the charge to be read or written. A bit line 200B is arranged perpendicular to the word line 200W and is also connected to the transistor 200T. When reading, the charge on the capacitor 200C is sensed through the bit line 200B, which determines whether the stored value is 0 or 1. When writing, the bit line 200B is used to set the charge on the capacitor 200C to the desired logical value. Thus, the word line 200W selects the memory cell 202, and the bit line 200B carries the data during the operation.

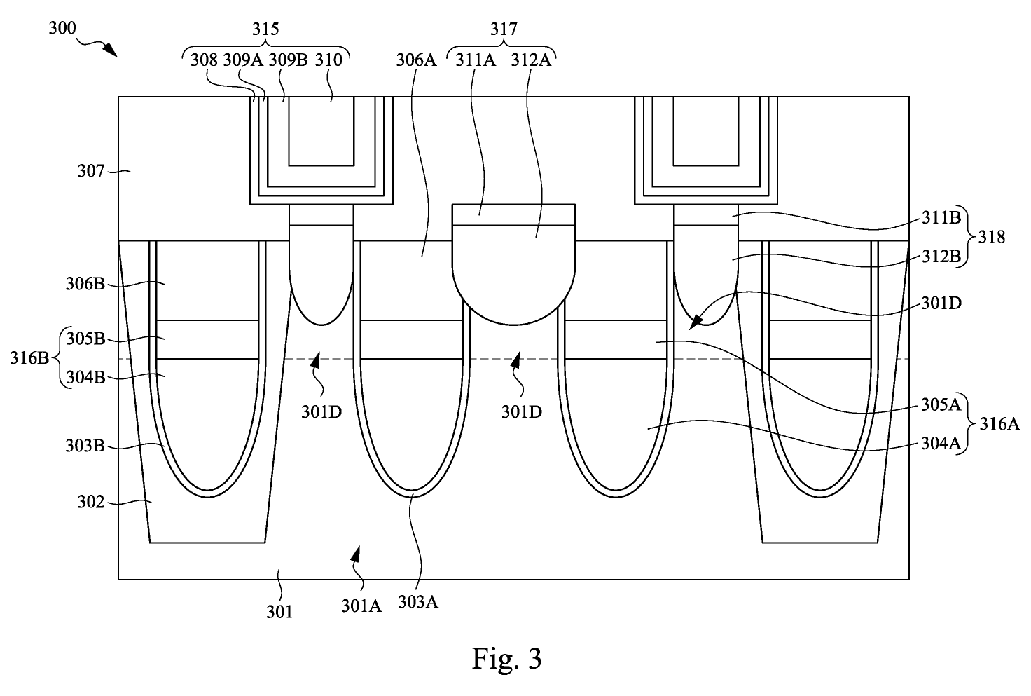

FIG. 3 is a cross-sectional view of a memory device according to some embodiments of the present disclosure. Shown there is a memory device 300. In some embodiments, the cross-sectional view of the memory device 300 may be an example of the memory device 200 as discussed in FIG. 2.

The memory device 300 includes a substrate 301. In some embodiments, the substrate 301 can be suitable semiconductive material, such as silicon, silicon carbide, gallium arsenic, gallium phosphide, germanium, indium antimonide, indium phosphide, indium arsenide, or the like. The substrate 301 may also be doped with suitable dopants. For example, the substrate 301 may be doped with p-type dopants, such as boron (B), gallium (Ga), indium (In), aluminium (Al), or the like. In other embodiments, the substrate 301 may be doped with n-type dopants, such as phosphorus (P), arsenic (As), or antimony (Sb), or the like.

Isolation structures 302 are disposed within the substrate 301. The isolation structures 302 can be suitable isolation structures, such as shallow trench isolation (STI) structures. In the cross-sectional view of FIG. 3, shown there are two isolation structures 302 that define an active area 301A where at least one transistor is formed thereon. In some embodiments, the isolation structures 302 may be made of suitable dielectric material, such as silicon oxide, silicon nitride or the like.

The memory device 300 further includes a plurality of word line structures 316A and 316B. In greater detail, in the cross-sectional view of FIG. 3, the word line structures 316A are embedded in the active area 301A of the substrate 301, while the word line structures 316B are embedded in the isolation structures 302.

The memory device 300 further includes dielectric layers 306A over the respective word line structures 316A, and dielectric liners 303A lining the respective word line structures 316A and the respective dielectric layers 306A. In some embodiments, the dielectric layers 306A may include suitable dielectric material, such as silicon oxide, silicon nitride or the like. In some embodiments, the dielectric liners 303A may include suitable dielectric material, such as silicon oxide, silicon nitride or the like.

Similarly, the memory device 300 further includes dielectric layers 306B over the respective word line structures 316B, and dielectric liners 303B lining the respective word line structures 316B and the respective dielectric layers 306B. The materials of the dielectric layers 306B and the dielectric liners 303B may be similar to those described with respect to the dielectric layers 306A and the dielectric liners 303A, and thus relevant details will not be repeated for brevity.

In some embodiments, each of the word line structures 316A includes a bottom conductive material 304A and a top conductive material 305A over the bottom conductive material 304A. In some embodiments, the bottom conductive material 304A and the top conductive material 305A are made of different materials. In some embodiments, the bottom conductive material 304A may include suitable conductive material, such as cobalt, nickel, titanium, titanium nitride, tungsten, tungsten nitride, the like, or the combination thereof. For example, in some embodiments, the combination of titanium nitride and tungsten are used as the bottom conductive material 304A. In some embodiments, the top conductive material 305A may be suitable material to reduce the band-bending between the active area 301A and the dielectric liner 303A. The top conductive material 305A may be a semiconductive material or conductive material. In some embodiments, polysilicon is used for the top conductive material 305A. In some other embodiments, doped polysilicon is used for the top conductive material 305A. Although the top conductive material 305A is illustrated having a rectangular cross-section, the present disclosure is not limited thereto. In other embodiments, the cross-section of the top conductive material 305A can also be half-circle, triangle, trapezoid, reverse-trapezoid, irregular.

With respect to the word line structures 316B, each of the word line structures 316B includes a bottom conductive material 304B and a top conductive material 305B over the bottom conductive material 304B. The materials of the bottom conductive material 304B and the top conductive material 305B may be similar to those described with respect to the bottom conductive material 304A and the top conductive material 305A, and thus relevant details will not be repeated for brevity.

The memory device 300 further includes doped regions 301D within the active area 301A of the substrate 301, in which a pair of doped regions 301D are disposed on opposite sides of the word line structures 316A. In some embodiments, the doped regions 301D may include opposite conductivity type than the substrate 301. For example, when the substrate 301 is a p-type substrate, the doped regions 301D may be n-type doped regions. Similarly, when the substrate 301 is an n-type substrate, the doped regions 301D may be p-type doped regions.

Here, the word line structure 316A, the dielectric liner 303A, the pair of doped regions 301D on opposite sides of the word line structure 316A, and the active area 301A of the substrate 301 may collective serve as the transistor of the memory device 300 (e.g. the transistor 200T of FIG. 2). In greater detail, the word line structure 316A may serve as the gate electrode of the transistor, the dielectric liner 303A may serve as the gate dielectric of the transistor, the active area 301A of the substrate 301 may serve as the channel region of the transistor, and the doped regions 301D may serve as source/drain regions of the transistor.

The memory device 300 further includes a bit line structure 317 over the substrate 301 and electrically coupled with one of the doped regions 301D. In some embodiments, the bit line structure 317 may include a buried contact 312A and a bit line 311A over the buried contact 312A. In some embodiments, the buried contact 312A has a portion embedded in the substrate 301 and a portion protruding from the substrate 301. In some embodiments, a material of the buried contact 312A may be doped silicon or polysilicon. In some embodiments, a material of the bit line 311A may be suitable conductive material, such as tungsten, tungsten nitride, titanium nitride, the like, or the combination thereof.

The memory device 300 further includes capacitor contact structures 318 over the substrate 301 and electrically coupled with the doped regions 301D. In some embodiments, each of the capacitor contact structures 318 may include a buried contact 312B and a metal contact 311B over the buried contact 312B. In some embodiments, the buried contact 312B has a portion embedded in the substrate 301 and a portion protruding from the substrate 301. In some embodiments, the materials of the buried contact 312B and the metal contact 311B may be similar to those described with respect to the buried contact 312A and bit line 311A, and thus relevant details will not be repeated for brevity.

The memory device 300 further includes capacitor structures 315 over the respective capacitor contact structures 318. In some embodiments, each of the capacitor structures 315 includes a lower electrode 308, a first dielectric 309A, a second dielectric 309B, and an upper electrode 310, in which the first dielectric 309A and the second dielectric 309B are disposed between the upper electrode 310 and the lower electrode 308. In some embodiments, the lower electrode 308, the first dielectric 309A and the second dielectric 309B may include U-shape cross-section.

The capacitor structures 315 of FIG. 3 may be similar to the capacitor structure 10 as discussed in FIG. 1. In greater detail, the lower electrode 308, the first dielectric 309A, the second dielectric 309B, and the upper electrode 310 of the capacitor structures 315 may include similar materials and formation methods as the bottom electrode 100, the first dielectric 112, the second dielectric 114, and the top electrode 120 of the capacitor structures 10, respectively. Accordingly, relevant details will not be repeated for brevity.

The memory device 300 further includes a dielectric layer 307 over the substrate 301 and laterally surrounding the bit line structure 317, the capacitor contact structures 318, and the capacitor structures 315. In some embodiments, the dielectric layer 307 may be formed of, for example, silicon oxide, borophosphosilicate glass, undoped silicate glass, fluorinated silicate glass, low-k dielectric materials, the like, or a combination thereof.

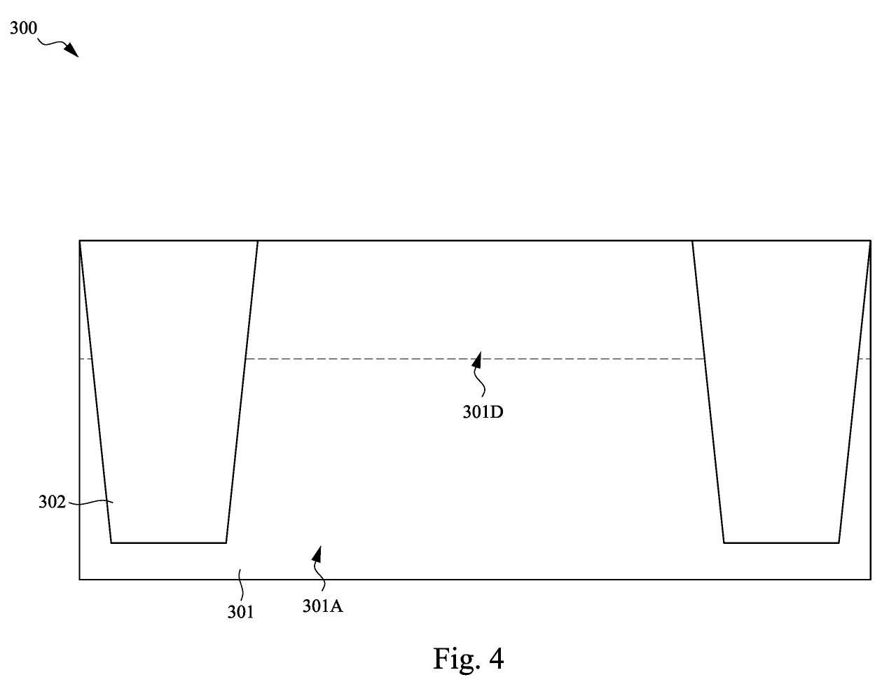

FIGS. 4 to 12 are cross-sectional views at various stages of forming a memory device according to some embodiments in the present disclosure. In greater detail, FIGS. 4 to 12 illustrate a method for forming the memory device 300 as discussed in Fig, 3. Accordingly, similar elements are labeled the same, and relevant details will not be repeated for brevity.

Referring to FIG. 4, a substrate 301 is provided. Isolation structures 302 are formed in the substrate 301 to define an active area 301A. For example, a series of deposition processes may be performed to deposit a pad oxide layer (not shown) and a pad nitride layer (not shown) over the substrate 301. A photolithography process may be performed to define the positions of the isolation structures 302. After the photolithography process, an etch process, such as an anisotropic dry etch process, may be performed to form trenches penetrating through the pad oxide layer, the pad nitride layer, and the substrate 301. In some embodiments, the cleaning process may be performed by suitable cleaning method, such as wet clean. An insulating material may be deposited into the trenches and a planarization process, such as chemical mechanical polishing, may be subsequently performed to remove excess filling material until the substrate 301 is exposed. After the isolation structures 302 are formed, a doped region 301D may be formed within the active area 301A of the substrate 301 through an implantation process.

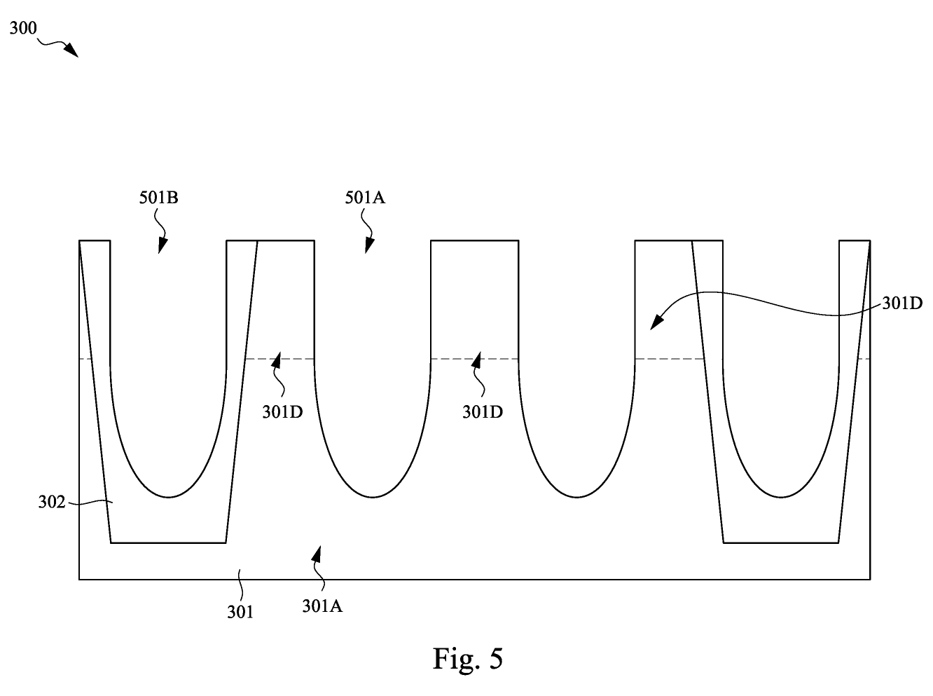

Referring to FIG. 5, trenches 501A and 501B are formed in the substrate 301 and the isolation structures 302, respectively. In some embodiments, a patterned mask (e.g., photoresist) is formed over the substrate 301, in which the patterned mask may include openings that define the positions of the trenches 501A and 501B. Afterwards, an etching process may be performed from the openings of the patterned mask to remove portions of the substrate 301 and the isolation structures 302, so as to form the trenches 501A and 501B. In some embodiments, the etching process may be suitable etching process, such as wet etch or dry etch. In some embodiments, the anisotropic etching process may be performed, such as RIE, DRIE, or the like. In some embodiments, the aspect ratio of trench 501A may be different from (or the same as) the aspect ratio of trench 501B.

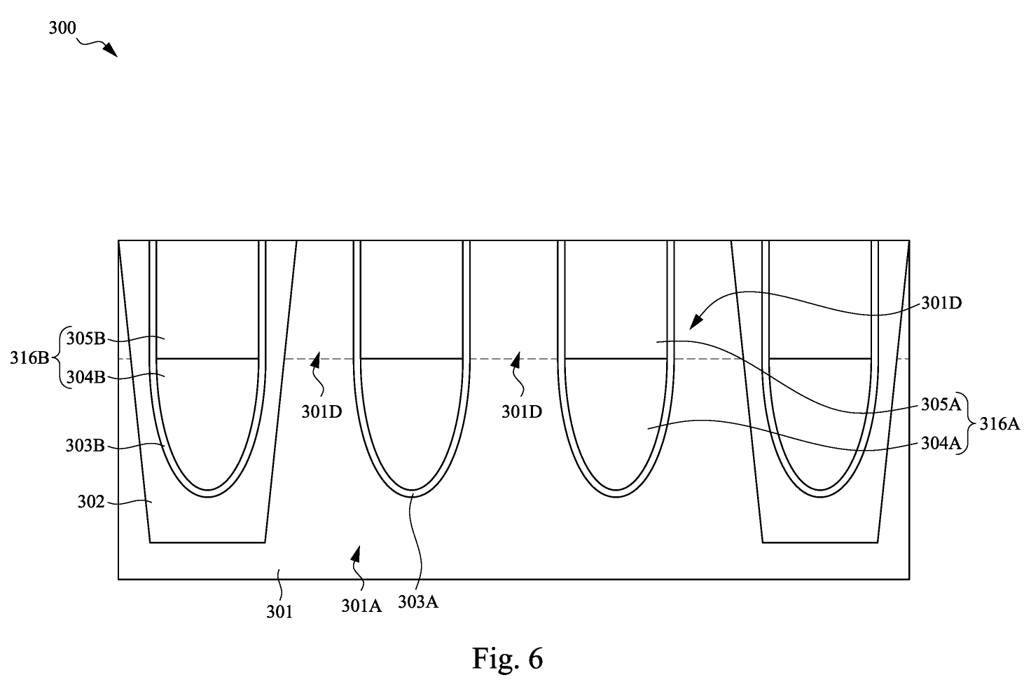

Referring to FIG. 6, dielectric liners 303A and word line structures 316A are formed in the trenches 501A, and the dielectric liners 303B and word line structures 316B are formed in the trenches 501B, respectively. The word line structure 316A includes a bottom conductive material 304A and a top conductive material 305A over the bottom conductive material 304A. The word line structure 316B includes a bottom conductive material 304B and a top conductive material 305B over the bottom conductive material 304B.

In some embodiments, a first deposition process may be performed to form a material of the dielectric liner 303A and 303B over the substrate 301 and lining sidewalls of the trenches 501A and 501B. In some embodiments, the first deposition process may be suitable deposition method, such as CVD, PECVD, low pressure CVD (LPCVD), ultra-high vacuum CVD (UHVCVD), atomic layer deposition (ALD), or the like.

Afterwards, a second deposition process may be performed to form a material of the bottom conductive materials 304A and 304B over the substrate 301 and overfilling the trenches 501A and 501B. Then, an etching back process is performed to lower top surface of the material of the bottom conductive materials 304A and 304B.

Then, a third deposition process may be performed to form a material of the top conductive materials 305A and 305B and overfilling the trenches 501A and 501B.

After the deposition process, a planarization process, such as CMP, may be performed on the material of the top conductive materials 305A and 305B until the substrate 301 is exposed. As a result, a top surface of the substrate 301, a top surface of top conductive material 305A, a top surface of top conductive material 305B, and a top surface of isolation structure 302 are substantially coplanar. In some embodiments, a cleaning process may be performed after the planarization process.

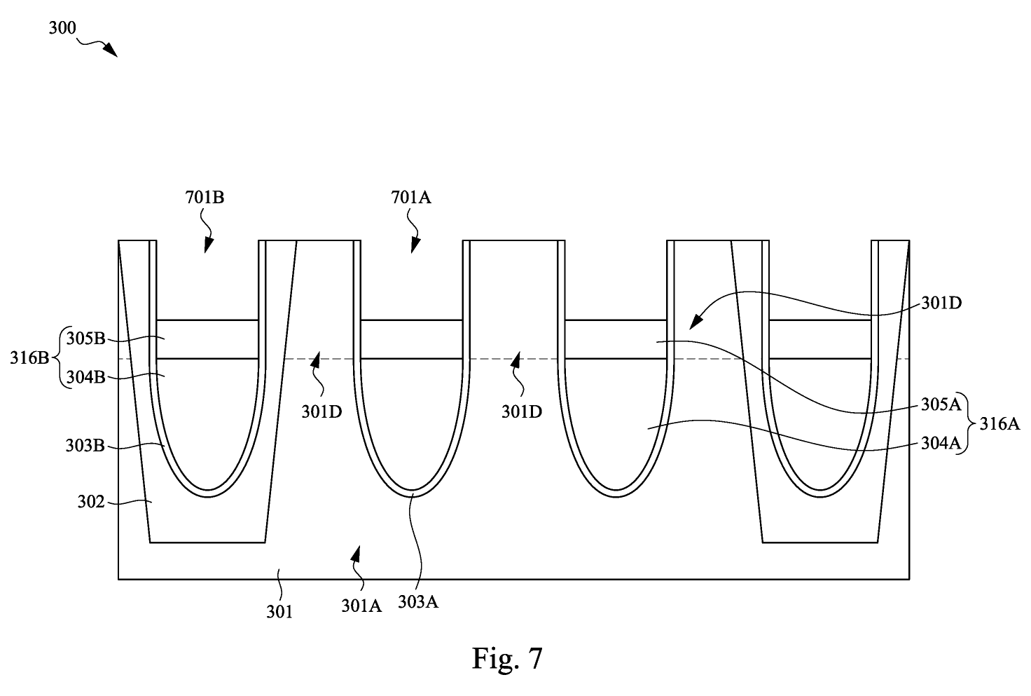

Referring to FIG. 7, an etching back process may be performed to lower top surfaces of the top conductive materials 305A and 305B to form recesses 701A and 701B over the word line structures 316A and 316B, respectively.

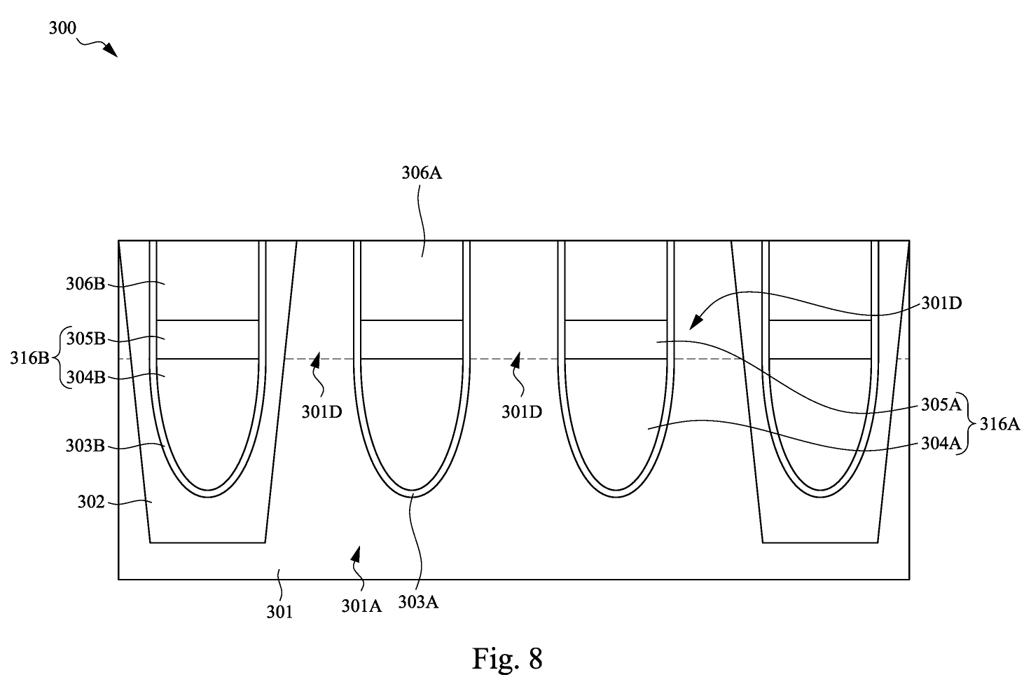

Referring to FIG. 8, dielectric layers 306A and 306B are formed over the word line structures 316A and 316B, respectively. In some embodiments, a deposition process may be performed to form a dielectric material over the substrate 301 and covering the word line structures 316A and 316B. Then, a planarization process may be performed to remove excess dielectric material until the substrate 301 is exposed. In some embodiments, the planarization process may be performed to make a top surface of the dielectric layer 306A and the top surface of the dielectric layer 306B coplanar with the surface of the substrate 301.

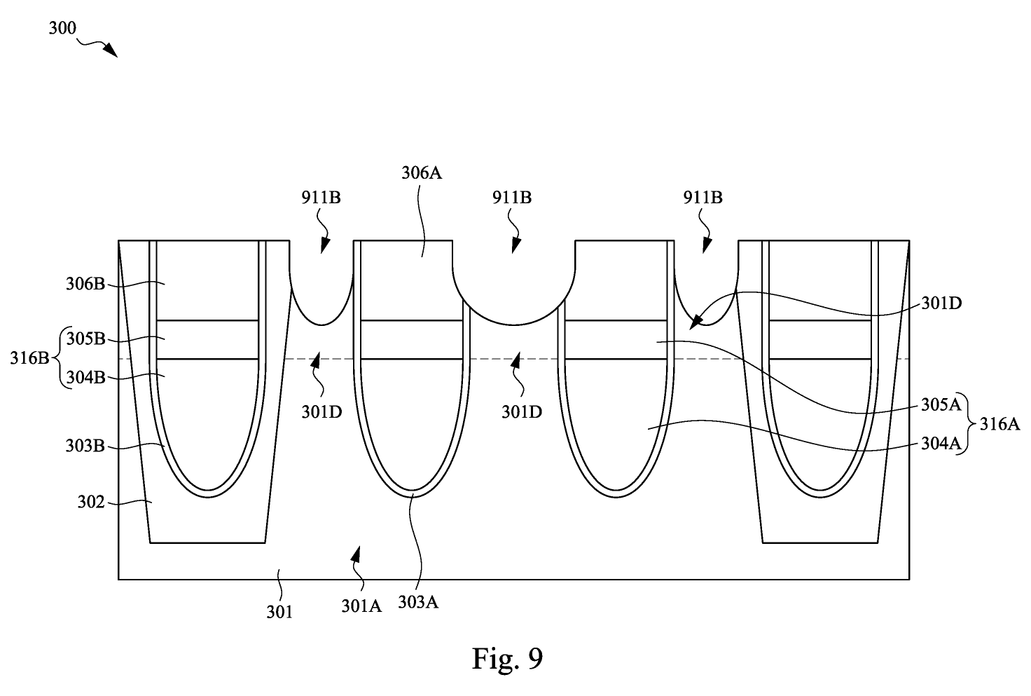

Referring to FIG. 9, recesses 911A and recesses 911B are formed in the doped regions 301D of the substrate 301. In some embodiments, the bottom of the recesses 911A and 911B may be higher than the top surface of the top conductive material 305A. In some embodiments, a patterned mask (not shown) is formed over the substrate 301, and an etching process is performed to remove portions of the substrate 301 exposed through the patterned mask to form the recesses 911A and 911B. In some embodiments, a clean process may be performed after the etching process. In some embodiments, the recess 911A may be formed between adjacent dielectric layers 306A. In some embodiments, the recess 911B may be formed between adjacent dielectric layers 306A and 306B.

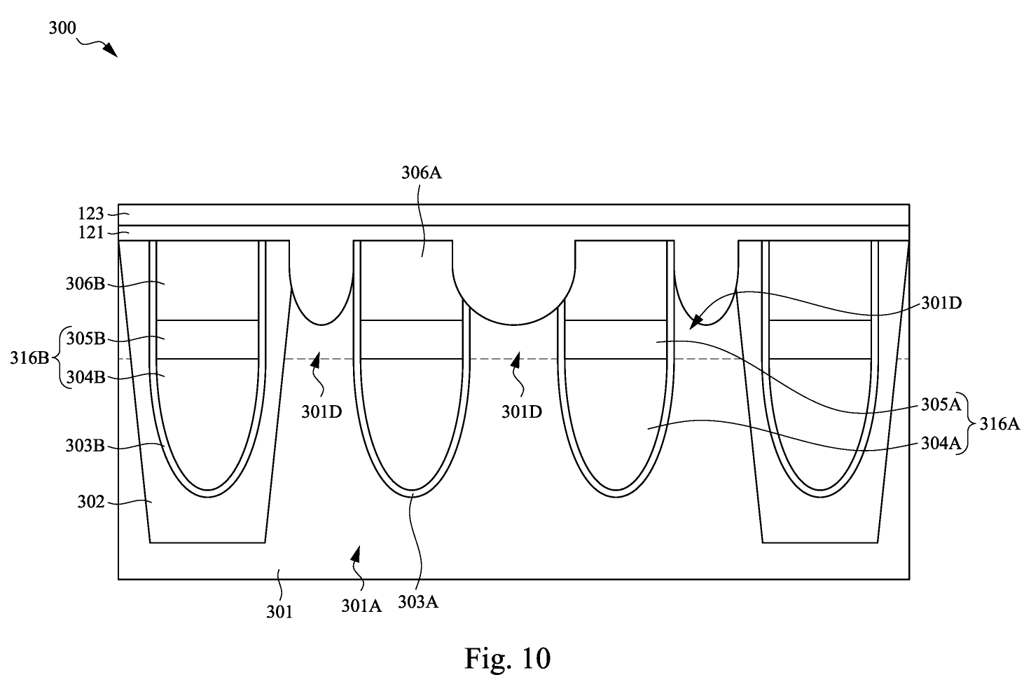

Referring to FIG. 10, a first conductive layer 121 is formed over the substrate 301, and a second conductive layer 123 is formed over the first conductive layer 121. In some embodiments, the first conductive layer 121 may fill the recesses 911A and 911B and may be in contact with the doped regions 301D. In some embodiments, the first conductive layer 121 and the second conductive layer 123 may be formed using suitable deposition process.

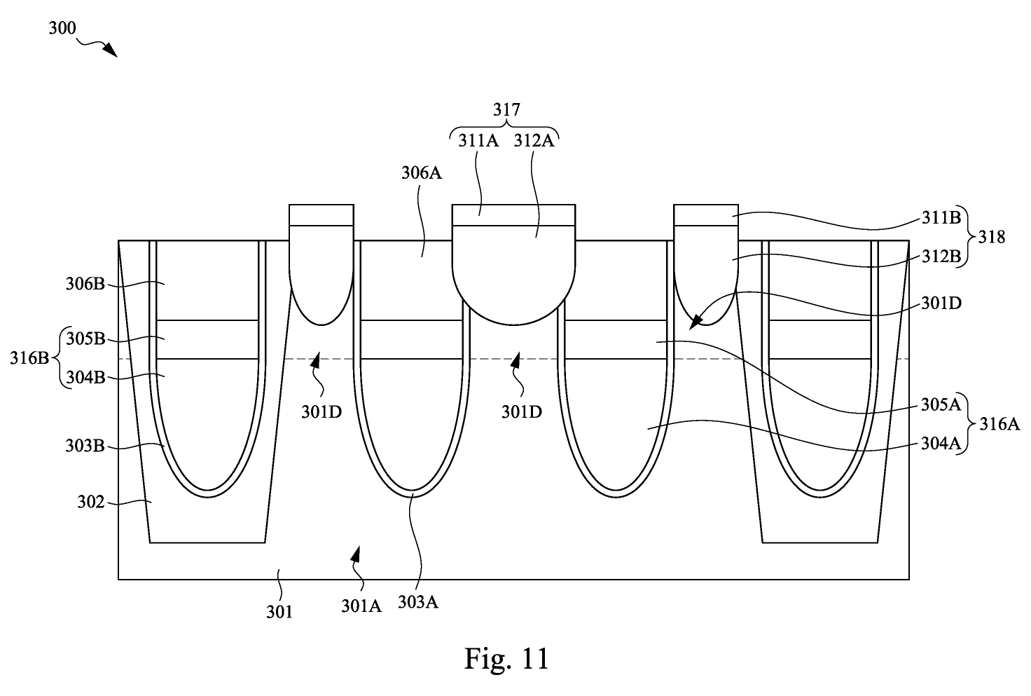

Referring to FIG. 11, the first conductive layer 121 and the second conductive layer 123 are patterned to form a bit line structure 317 and capacitor contact structures 318. In some embodiments, the bit line structure 317 includes a buried contact 212A and bit line 211A over the buried contact 212A, in which the buried contact 212A is a remaining portion of the first conductive layer 121, and the bit line 211A is a remaining portion of the second conductive layer 123. On the other hand, the capacitor contact structures 318 includes a buried contact 212B and metal contact 211B over the buried contact 212B, in which the buried contact 212B is a remaining portion of the first conductive layer 121, and the metal contact 211B is a remaining portion of the second conductive layer 123.

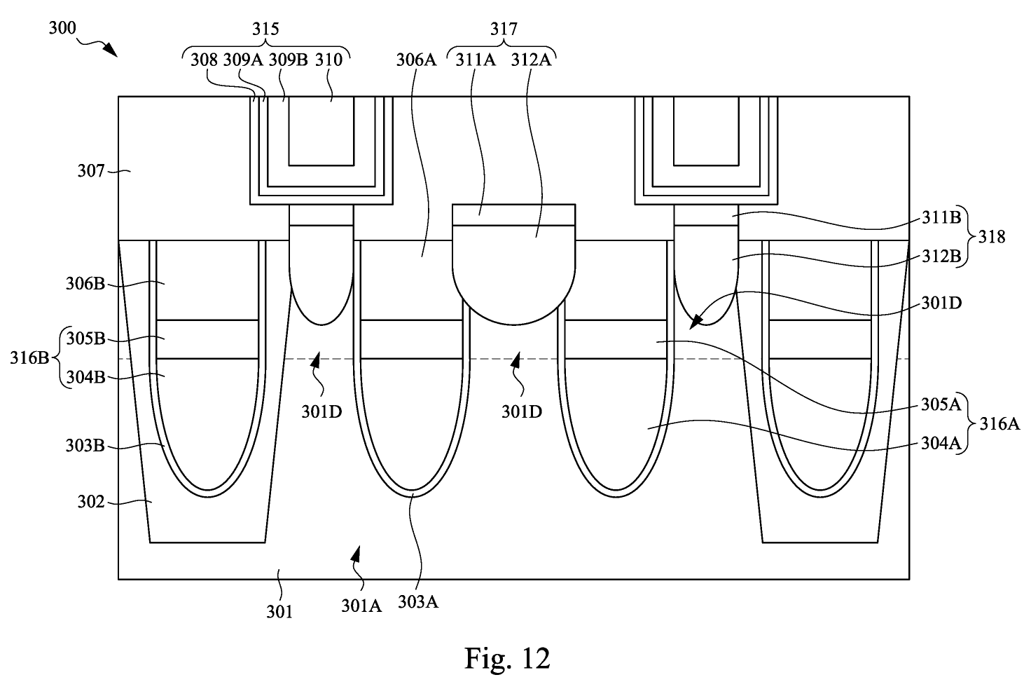

Referring to FIG. 12, a dielectric layer 307 is formed over the substrate 301 and covering the bit line structure 317 and capacitor contact structures 318. Then, capacitor structures 315 are formed in the dielectric layer 307 and in contact with the respective capacitor contact structures 318. In some embodiments, the dielectric layer 307 may be formed using suitable deposition process. In some embodiments, the capacitor structures 315 may be formed by, for example, patterning the dielectric layer 307 to forming openings exposing the capacitor contact structures 318, depositing a lower electrode 308, a first dielectric 309A, a second dielectric 309B, and an upper electrode 310 in the openings, and then performing a planarization process until the dielectric layer 307 exposed.

In some embodiments, additional processes and steps may be performed to accomplish the fabrication process of the memory device. In some embodiments, additional back end of line (BEOL) processes may be performed on the memory device 300.

Although the present invention has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims.

What is claimed is:

1. A memory device, comprising:
a substrate; and
a capacitor structure over the substrate, comprising:
a lower electrode;
a capacitor dielectric over the lower electrode and having a first dielectric and a second dielectric over the first dielectric, wherein the first dielectric is made of hafnium oxide and the second dielectric is made of zirconium oxide; and
an upper electrode over the second dielectric.

2. The memory device of claim 1, wherein the second dielectric is doped with aluminum.

3. The memory device of claim 2, wherein an aluminum concentration of the second dielectric is from about 1% to about 8%.

4. The memory device of claim 2, wherein the first dielectric is free of aluminum.

5. The memory device of claim 1, wherein the first dielectric has a first thickness, and the second dielectric has a second thickness different from the first thickness.

6. The memory device of claim 5, wherein the first thickness is less than the second thickness.

7. The memory device of claim 5, wherein the first thickness of the first dielectric is from about 0.5 nm to about 2.0 nm, and the second thickness of the second dielectric is from about 3.0 nm to about 7.0 nm.

8. The memory device of claim 1, wherein the capacitor dielectric has a crystalline structure with tetragonal phase and orthorhombic phase.

9. The memory device of claim 8, wherein a ratio of tetragonal phase to orthorhombic phase of the capacitor dielectric is about 0.1 to about 0.3.

10. The memory device of claim 1, further comprising:
a word line structure over the substrate; and
a bit line structure over the substrate and electrically connected to a doped region of the substrate on a first side of the word line structure, wherein the capacitor structure is electrically connected to another doped region of the substrate on a second side of the word line structure.

11. A method for forming a memory device, comprising:
forming a capacitor structure over a substrate, comprising:
depositing a bottom electrode;
depositing a first dielectric over the bottom electrode, wherein the first dielectric is made of hafnium oxide;
depositing a second dielectric over the first dielectric, wherein the second dielectric is made of zirconium oxide; and
depositing a top electrode over the second dielectric.

12. The method of claim 11, wherein the second dielectric is doped with aluminum.

13. The method of claim 12, wherein an aluminum concentration of the second dielectric is from about 1% to about 8%.

14. The method of claim 12, wherein the first dielectric is free of aluminum.

15. The method of claim 11, wherein the first dielectric has a first thickness, and the second dielectric has a second thickness different from the first thickness.

16. The method of claim 15, wherein the first thickness is less than the second thickness.

17. The method of claim 11, further comprising performing an anneal process after depositing the second dielectric, such that a combination of the first dielectric and the second dielectric has a crystalline structure with tetragonal phase and orthorhombic phase.

18. The method of claim 17, wherein a temperature of the anneal process is between about 400° C to about 500° C.

19. The method of claim 17, wherein a ratio of tetragonal phase to orthorhombic phase is about 0.1 to about 0.3.

20. The method of claim 11, further comprising:
forming a word line structure over the substrate; and
forming a bit line structure over the substrate and electrically connected to a doped region of the substrate on a first side of the word line structure, wherein the capacitor structure is electrically connected to another doped region of the substrate on a second side of the word line structure.
